(19) United States
(12) Patent Application Publication
(10) Pub. No.: US 2011/0274131 A1
(43) Pub. Date: Nov. 10, 2011

(54) TWO-DIMENSIONAL SURFACE-EMITTING LASER ARRAY ELEMENT, SURFACE-EMITTING LASER DEVICE AND LIGHT SOURCE

(75) Inventors: Keishi Takaki, Tokyo (JP); Hirotatsu Ishii, Tokyo (JP); Hitoshi Shimizu, Tokyo (JP); Norihiro Iwai, Tokyo (JP)

(73) Assignee: FURUKAWA ELECTRIC CO., LTD., Tokyo (JP)

(21) Appl. No.: 13/142,996

(22) PCT Filed: Jan. 20, 2010
(86) PCT No.: PCT/JP2010/050649

§ 371 Date: Jun. 30, 2011

(30) Foreign Application Priority Data
Jan. 20, 2009 (JP) 2009-009983

(51) Int. Cl. H01S 5/42

(52) U.S. Cl. 372/50.124

(57) ABSTRACT

Included are a plurality of surface-emitting laser elements each of which includes a substrate; a lower multilayer reflective mirror and an upper multilayer reflective mirror that are formed on the substrate and are formed from a periodic structure of a high-refractive index layer and a low-refractive index layer; an active layer provided between the lower multilayer reflective mirror and the upper multilayer reflective mirror; a lower contact layer positioned between the active layer and the lower multilayer reflective mirror, and is extended to an outer peripheral side of the upper multilayer reflective mirror; a lower electrode formed on a surface of a portion where the lower contact layer is extended; and an upper electrode for injecting a current to the active layer, wherein the surface-emitting laser elements are electrically connected in series to each other to form a series-connected element array. This allows provision of a two-dimensional surface-emitting laser array element capable of achieving high energy conversion efficiency with a simple structure and capable of high integration, and a surface-emitting laser device and a light source using the same.

### RELATED APPLICATIONS

The present application is a National Phase of International Application Number PCT/JP2010/050649, filed Jan. 20, 2010, and claims priority from, Japanese Application Number 2009-009983, filed Jan. 20, 2009.

### FIELD

The present invention relates to a two-dimensional surface-emitting laser array element, and a surface-emitting laser device and a light source using the same.

### BACKGROUND

Conventionally, as a signal light source for optical interconnection, a two-dimensional surface-emitting laser array element having a plurality of surface-emitting laser elements formed on a substrate is used. The two-dimensional surface-emitting laser array element is structured so that each of the surface-emitting laser elements outputs an independent laser optical signal.

Meanwhile, a technology using the two-dimensional surface-emitting laser array element as a watt-class high-power laser light source is disclosed (see Nonpatent Document 1). The two-dimensional surface-emitting laser array element is structured so that laser optical powers emitted from the surface-emitting laser elements are converged so as to function as one light source, unlike the signal light source. Moreover, the two-dimensional surface-emitting laser array element is expected as a high-power laser light source with extremely high reliability because there is no catastrophic optical damage (COD) at an facet unlike an edge-emitting laser element. In addition, a power conversion efficiency defined as a ratio of laser optical power to electric power applied to the element is reported as 51% at maximum in the two-dimensional surface-emitting laser array element described in Nonpatent Document 1, which is sufficiently high so that the power conversion efficiency can be competitive with that of the edge-emitting laser element.

Citation List

Nonpatent Document

Nonpatent Document 1: Jean-Francois Seurin, et al., “High-power high-efficiency 2D VCSEL arrays”, Proc. SPIE, Vol. 6908, 690808 (2008)

### SUMMARY

### Technical Problem

However, the two-dimensional surface-emitting laser array element described in Nonpatent Document 1 has a problem that even though the power conversion efficiency in the element is high, energy conversion efficiency cannot be increased when considering the element including a power supply device for driving the element.

That is, in the two-dimensional surface-emitting laser array element described in Nonpatent Document 1, the surface-emitting laser elements forming the element are electrically connected in parallel to each other, and thus, to achieve, for example, a laser power of 231 W, a voltage of about 3 V is applied to the elements and a current of 320 A is flowed thereto to drive the elements. However, in the power supply device for applying such a low voltage and a large current, the energy conversion efficiency generally becomes low. Therefore, the two-dimensional surface-emitting laser array element described in Nonpatent Document 1 has such a problem that the energy conversion efficiency cannot be increased when the element including the power supply device is considered.

The two-dimensional surface-emitting laser array element described in Nonpatent Document 1 has a problem that the elements cannot be highly integrated because a wiring pattern for connecting the elements in parallel is provided therein.

The present invention has been achieved to solve the problems, and an object of the present invention is to provide a two-dimensional surface-emitting laser array element capable of achieving high energy conversion efficiency with a simple structure and capable of high integration, and a surface-emitting laser device and a light source using the same.

### Solution to Problem

To solve the problems and to attain the object, there is provided a two-dimensional surface-emitting laser according to the present invention including: a plurality of surface-emitting laser elements each of which includes a substrate; a lower multilayer reflective mirror and an upper multilayer reflective mirror that are formed on the substrate and are formed from a periodic structure of a high-refractive index layer and a low-refractive index layer; an active layer provided between the lower multilayer reflective mirror and the upper multilayer reflective mirror; a lower contact layer positioned between the active layer and the lower multilayer reflective mirror, and is extended to an outer peripheral side of the upper multilayer reflective mirror; a lower electrode formed on a surface of a portion where the lower contact layer is extended; and an upper electrode for injecting a current to the active layer, wherein the surface-emitting laser elements are electrically connected in series to each other to form a series-connected element array.

There is provided the two-dimensional surface-emitting laser according to the present invention, wherein each of the surface-emitting laser elements further includes an upper contact layer positioned between the active layer and the upper multilayer reflective mirror; and the upper electrode provided on the upper contact layer.

There is provided the two-dimensional surface-emitting laser according to the present invention, wherein at least part of the upper multilayer reflective mirror is formed from a dielectric material.

There is provided the two-dimensional surface-emitting laser array element according to the present invention, wherein the surface-emitting laser elements form a one-dimensionally arranged and serially connected element array.

There is provided the two-dimensional surface-emitting laser array element according to the present invention, wherein the upper electrode of the surface-emitting laser element and the lower electrode of the surface-emitting laser element adjacent thereto are connected to each other with an extraction electrode.

There is provided the two-dimensional surface-emitting laser array element according to the present invention, further including the series-connected element array provided in plurality, wherein the series-connected element arrays are electrically connected in parallel to each other.

There is provided the two-dimensional surface-emitting laser array element according to the present invention, wherein in the series-connected element array provided in plurality, the surface-emitting laser elements forming the series-connected element arrays adjacent to each other are mutually displaced from each other in a longitudinal direction of the series-connected element array.

There is provided a surface-emitting laser device including: a two-dimensional surface-emitting laser array element according to the present invention; and a micro lens array that changes a laser light output from each of the surface-emitting laser elements forming the two-dimensional surface-emitting laser array element to a collimated light.

There is provided a light source formed from a two-dimensional surface-emitting laser array element according to the present invention, wherein emission wavelengths of the surface-emitting laser elements are equal to each other.

There is provided a light source formed from a two-dimensional surface-emitting laser array element according to the present invention, wherein at least part of emission wavelengths of the surface-emitting laser elements is different from emission wavelengths of the other surface-emitting laser elements.

### Advantageous Effects of Invention

According to the present invention, because the surface-emitting laser elements are connected in series with the simple structure, there is such an effect that it is possible to implement the two-dimensional surface-emitting laser array element capable of achieving high energy conversion efficiency with the simple structure and capable of high integration, and also to implement the surface-emitting laser device and the light source.

### BRIEF DESCRIPTION OF DRAWINGS

FIG. 1 is a schematic plan view of a two-dimensional surface-emitting laser array element according to a first embodiment of the present invention.

FIG. 2 is a view illustrating enlarged one of surface-emitting laser elements in an A-A line cross section of the two-dimensional surface-emitting laser array element shown in FIG. 1.

FIG. 3 is an explanatory diagram for explaining one example of a method for manufacturing the two-dimensional surface-emitting laser array element shown in FIGS. 1 and 2.

FIG. 4 is an explanatory diagram for explaining one example of the method for manufacturing the two-dimensional surface-emitting laser array element shown in FIGS. 1 and 2.

FIG. 5 is an explanatory diagram for explaining one example of the method for manufacturing the two-dimensional surface-emitting laser array element shown in FIGS. 1 and 2.

FIG. 6 is a graph representing a relationship between drive current and optical power of 50×10 surface-emitting laser array elements.

FIG. 7 is a schematic diagram illustrating a schematic structure of a surface-emitting laser device according to a second embodiment and an enlarged part of the structure.

### DESCRIPTION OF EMBODIMENTS

The two-dimensional surface-emitting laser array according to the present invention is characterized in that elements forming the two-dimensional surface-emitting laser array element are connected in series to form a series-connected element array, and the surface-emitting laser elements forming the two-dimensional surface-emitting laser array element are so-called intracavity type surface-emitting laser elements.

According to the present invention, because each of the surface-emitting laser elements has low element resistance, which allows a series connection of these elements. Moreover, these surface-emitting laser elements are serially connected to obtain a surface-emitting laser array element, thus largely improving energy efficiency (for example, in a one-dimensional array (series-connected element array) in which 50 surface-emitting laser elements are serially connected to each other, according to the present invention, power supply devices with high power efficiency for supplying 100 V and 10 mA are connected to both ends thereof respectively, and the array can thereby be driven).

Furthermore, because there is no need to provide additional wiring between the elements of the series-connected element array, each interval between the elements can be reduced as compared with that of the conventional surface-emitting laser array element.

That is, the surface-emitting laser elements forming the two-dimensional surface-emitting laser array element according to the present invention are the intracavity type (at least one of contact layers for current injection is included inside an optical resonator mirror) surface-emitting laser elements. Therefore, it is necessary to provide a through hole communicated with the back side of a substrate in order to serially connect the conventional surface-emitting laser elements each having an electrode on the back side of the substrate. However, by adopting the structure of the present invention, an electrode to inject a current to an active layer can be provided only on one of the surfaces and the surface-emitting laser elements can thereby be integrated in high density as compared with the conventional surface-emitting laser array element.

Moreover, the present invention adopts double-intracavity type (two contact layers for current injection are included inside an optical resonator mirror) surface-emitting laser elements, and this enables the integration to be further increased as compared with a case where single-intracavity type surface-emitting laser elements are integrated. The reason is as follows. That is, in the double-intracavity type surface-emitting laser elements, the two contact layers are generally provided inside the resonator mirror. Meanwhile, in the single-intracavity type surface-emitting laser elements, one of the contact layers is provided on the resonator mirror. Therefore, in the double-intracavity type surface-emitting laser elements, a difference in height between an upper electrode and a lower electrode provided on the contact layers becomes extremely small as compared with the case of the single-intracavity type. As a result, when the series-connected element array is formed with the double-intracavity type surface-emitting laser elements, a surface area required for covering a step height on the surface and forming an electrode whose electrical wiring is secured becomes small, and this allows high integration thereof. For example, a difference in height between the surface-emitting laser elements is 4 μm to 5 μm in the single-intracavity type (structure where a p-side electrode being the upper electrode is formed on the semiconductor mirror), while it is suppressed to about one-tenth (to 0.5 μm) thereof in the double-intracavity type.

By adopting the double-intracavity type, the element resistance of the surface-emitting laser elements can also be decreased to 100Ω or less. Therefore, by using low element-resistance elements of 10Ω to 100Ω, especially, 50Ω or less, a large number of surface- emitting laser elements, such as 100 to 1000, are serially connected to form the two-dimensional surface-emitting laser array element.

Moreover, series-connected element arrays, each in which surface-emitting laser elements are serially connected to each other in a straight chain manner, can be closely arranged to each other without intervention of the wiring pattern, thus further increasing the integration per unit area.

Embodiments of the two-dimensional surface-emitting laser array element, the surface-emitting laser device, and the light source according to the present invention will be explained below with reference to the accompanying drawings. It should be noted that the present invention is not limited by the embodiments. In addition, the same signs are assigned to the same portions in the description of the drawings.

### First Embodiment

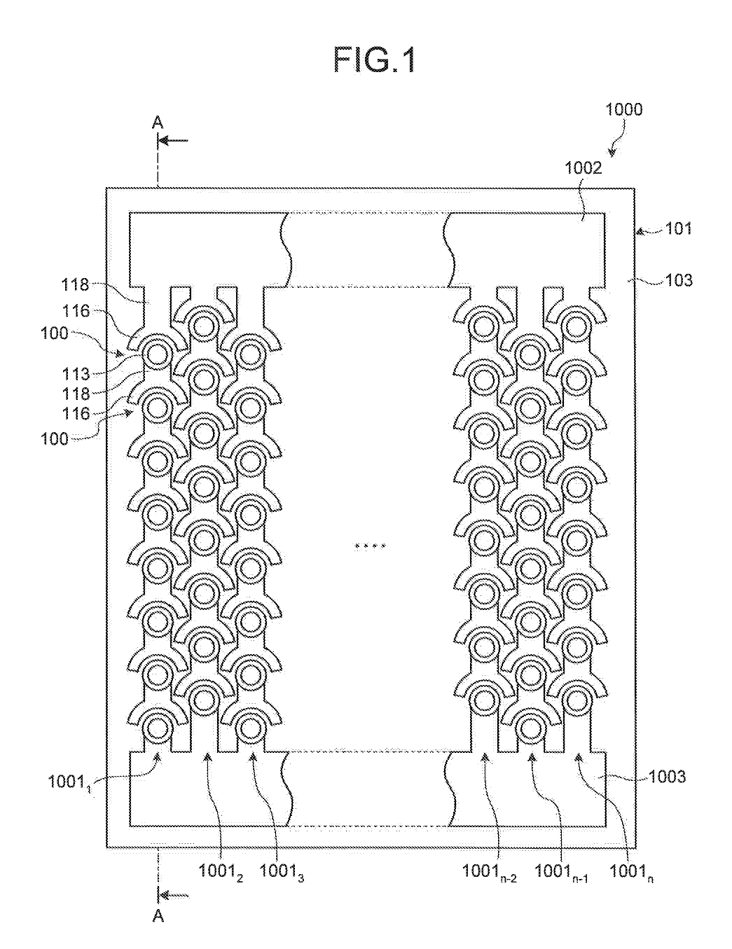

FIG. 1 is a schematic plan view of a two-dimensional surface-emitting laser array element 1000 according to a first embodiment of the present invention. As shown in FIG. 1, the two-dimensional surface-emitting laser array element 1000 includes series-connected elements array 1001₁ to 1001ₙ where n represents an integer of 2 or more, a common n-side electrode 1002, and a common p-side electrode 1003. Each of the series-connected elements array 1001₁ to 1001ₙ is formed from m pieces of surface-emitting laser elements 100, where m represents an integer of 2 or more. That is, the two-dimensional surface-emitting laser array element 1000 is formed from m×n surface-emitting laser elements 100. Although m and n are not limited, for example, m represents 10 to 100, and n represents 10 to 1000.

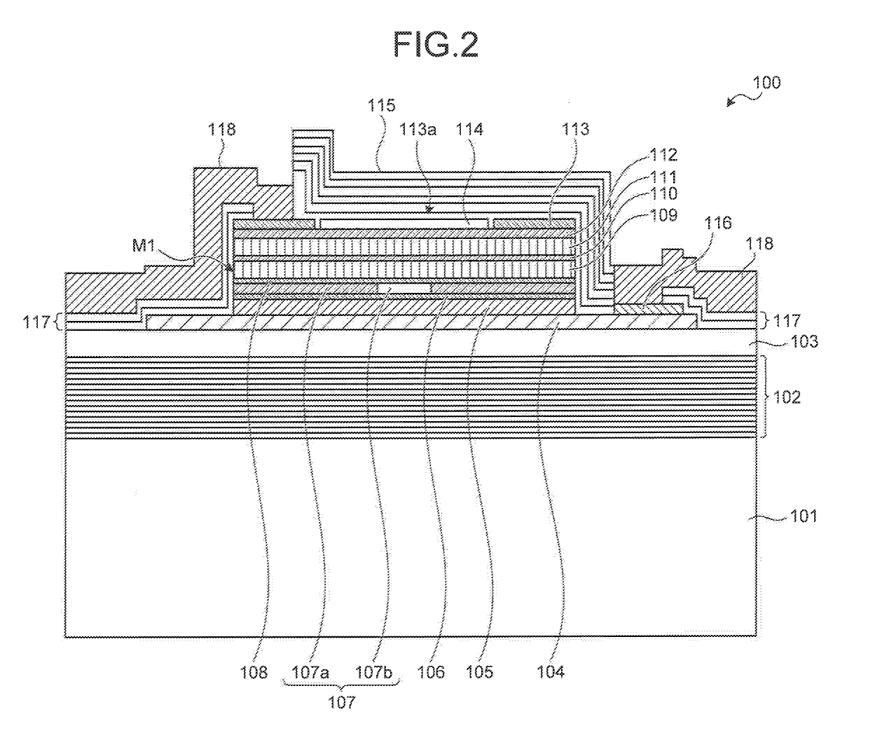

FIG. 2 is a view illustrating enlarged one of surface-emitting laser elements 100 in an A-A line cross section of the two-dimensional surface-emitting laser array element 1000 shown in FIG. 1. As shown in FIG. 2, the surface-emitting laser element 100 has a structure in which a substrate 101, a lower DBR mirror 102 being a lower multilayer film reflective mirror formed on the substrate 101, a buffer layer 103, an n-type contact layer 104, an active layer 105 having a multi-quantum well structure, a lower gradient composition layer 106, a current confinement layer 107 having a current confinement portion 107a located along the outer periphery and a circular current injection portion 107b located at the center of the current confinement portion 107a, an upper gradient composition layer 108, a p-type spacer layer 109, a p⁺-type current path layer 110, a p-type spacer layer 111, and a p⁺-type contact layer 112 are sequentially laminated on one another. The layers from the active layer 105 to the p⁺-type contact layer 112 form a cylindrical mesa post M1.

The substrate 101 is formed from, for example, undoped GaAs. The lower DBR mirror 102 is formed from 34 pairs of, for example, GaAs/Al_{0.9}Ga_{0.1}As layers. The buffer layer 103 is formed from, for example, undoped GaAs. The n-type contact layer 104 is formed from, for example, n-type GaAs. The active layer 105 has a structure, used for a laser light of, for example, 1100 nm band, in which an InGaAs layer whose number of layers is 3 and a GaAs barrier layer whose number of layers is 4 are alternately laminated, and the GaAs barrier layer being the lowest layer functions also as an n-type clad layer. As for the current confinement layer 107, the current confinement portion 107a is made of Al₂O₃, and the current injection portion 107b has a diameter of 6 μm to 7 μm and is made of AlAs. The lower gradient composition layer 106 and the upper gradient composition layer 108 are made of, for example, AlGaAs, and are structured so that Al composition thereof gradually increases as approaching to the current confinement layer 107 in their thickness direction. The p-type spacer layers 109 and 111, the p⁺-type current path layer 110, and the p⁺-type contact layer 112 are made of, for example, p-type and p⁺-type GaAs obtained by doping carbon thereinto, respectively. Acceptor or donor concentration of p-type or n-type layer is about 1×10¹⁸ cm⁻³ or more, and acceptor concentration of the p⁺-type layer is, for example, 1×10¹⁹ cm⁻³ or more.

Formed on the p⁺-type contact layer 112 is a p-side ring electrode 113 which is made of Pt/Ti, has an opening 113a at its center, and has an outer periphery matching the outer periphery of the mesa post M1. The outer diameter of the p-side ring electrode 113 is, for example, 30 μm, and the inner diameter of the opening 113a is, for example, 11 μm to 14 μm.

Formed inside the opening 113a of the p-side ring electrode 113 is a disk-shaped phase adjustment layer 114 made of, for example, silicone nitride(SiNₓ) being a dielectric material. The phase adjustment layer 114 has a function for appropriately adjusting a position of a node or an anti-node of a standing wave of light formed between the lower DBR mirror 102 and an upper DBR mirror 115.

Moreover, the upper DBR mirror 115 being an upper multilayer film reflective mirror made of a dielectric material is formed from the phase adjustment layer 114 over the outer periphery of the mesa post M1. The upper DBR mirror 115 is formed from 10 to 12 pairs of, for example, SiNₓ/SiO₂. However, a pair of, for example, α-Si/SiO₂ or α-Si/Al₂O₃ may be set to the number of pairs so that an appropriate reflectance of about 99% can be obtained according to a refractive index of the material. In addition, the n-type contact layer 104 is extended from the lower side of the mesa post M1 to the outer peripheral side of the upper DBR mirror 115, and a semi-circular n-side electrode 116 made of, for example, AuGeNi/Au is formed on the surface thereof. In the n-side electrode 116, for example, its outer diameter is 80 μm and its inner diameter is 40 μm. Formed in an area where the upper DBR mirror 115 is not formed is a passivation film 117 made of a dielectric material such as SiNₓ for surface protection.

An extraction electrode 118 made of Au is formed so as to contact the n-side electrode 116 through the opening formed on the passivation film 117. Meanwhile, an extraction electrode 118 made of Au is formed so as to contact the p-side ring electrode 113 through the opening formed on the passivation film 117.

As shown in FIG. 1, in the series-connected array element 1001₁, the extraction electrode 118 connected to the n-side electrode 116 of the surface-emitting laser element 100 is connected to the common n-side electrode 1002, and the extraction electrode 118 connected to the p-side ring electrode 113 is connected to the n-side electrode 116 of the adjacent surface-emitting laser element 100. In this manner, the series-connected array element 1001₁ has a structure in which a plurality of surface-emitting laser elements 100 are electrically connected in series to each other. Likewise, each of the other series-connected elements array 1001₂ to 1001ₙ has a structure in which a plurality of surface-emitting laser elements 100 are connected in series to each other.

Moreover, these series-connected elements array 1001₂ to 1001ₙ are electrically connected in parallel to each other with the common n-side electrode 1002 and the common p-side electrode 1003. The common n-side electrode 1002 and the common p-side electrode 1003 are electrically connected to an externally provided current supply circuit (not shown).

In the two-dimensional surface-emitting laser array element 1000, a voltage is applied to the surface-emitting laser elements 100 of each of the series-connected elements array 1001₂ to 1001ₙ from the current supply circuit through the common n-side electrode 1002 and the common p-side electrode 1003, and by injecting the current thereto, the current then mainly flows through the low-resistance p⁺-type contact layer 112 and p⁺-type current path layer 110, and the current path is confined in the current injection portion 107b by the current confinement layer 107, so that the current is supplied to the active layer 105 at high current density. As a result, the active layer 105 is injected with carrier to emit spontaneous emission. Of the spontaneous emission, a light of 1100 nm band being a laser oscillation wavelength forms a standing wave between the lower DBR mirror 102 and the upper DBR mirror 115, and the light is amplified by the active layer 105. When the injected current becomes a threshold or more, the light forming the standing wave oscillates, to output a laser light of, for example, 1100 nm band through the opening 113a of the p-side ring electrode 113.

Here, in each of the surface-emitting laser elements 100 forming the two-dimensional surface-emitting laser array element 1000, the n-type contact layer 104 positioned between the lower DBR mirror 102 and the active layer 105 is extended to the outer peripheral side of the upper DBR mirror 115, and the n-side electrode 116 is formed on the surface of the extended portion. In each of the surface-emitting laser elements 100, the p⁺-type contact layer 112 is positioned between the upper DBR mirror 115 and the active layer 105. That is, each of the surface-emitting laser elements 100 has a so-called double-intracavity type structure. Therefore, in the two-dimensional surface-emitting laser array element 1000, a series connection between adjacent surface-emitting laser elements 100 is implemented with a simple structure, and this allows achievement of high energy conversion efficiency when considering this element including the power supply device.

That is, as explained above, the conventional two-dimensional surface-emitting laser array element has a problem that the energy conversion efficiency cannot be increased when considering this element including the power supply device, because the surface-emitting laser elements forming this element are parallel-connected to each other.

However, if the adjacent surface-emitting laser elements in the conventional two-dimensional surface-emitting laser array element are serially connected to each other, a complicated structure and complicated manufacturing steps are required for connecting between the n-side electrode on the back side of the substrate and the p-side electrode on the front side of the substrate, in such a manner that through halls are formed on the substrate to provide wiring or the substrate is cleaved for each surface-emitting laser element so that the surface-emitting laser elements are arranged in series. In addition, these complexity and complication are increased more and more as the number of surface-emitting laser elements is increased in order to implement high laser output.

On the other hand, in each of the surface-emitting laser elements 100 forming the two-dimensional surface-emitting laser array element 1000, both of the p-side ring electrode 113 and the n-side electrode 116 are located on the front side of the substrate 101. Therefore, only by connecting the p-side ring electrode 113 and the n-side electrode 116 of the adjacent surface-emitting laser elements 100 using the extraction electrode 118, the series connection can be easily achieved.

According to this structure, an additional wiring pattern is not required for electric connection between the surface-emitting laser elements 100, which enables occupancy of the surface-emitting laser elements 100 on the substrate 101 to be increased and high-density integration to be achieved. As shown in FIG. 1, in adjacent series-connected elements array of the series-connected elements array 1001₁ to 1001ₙ, by arranging the surface-emitting laser elements 100 forming the respective series-connected elements array in such a manner that they are mutually displaced from each other in the longitudinal direction of the array, each interval between the series-connected elements array can be reduced, which allows a higher density thereof.

In addition, by serially connecting the surface-emitting laser elements 100 in this manner, the two-dimensional surface-emitting laser array element 1000 can be driven at a high voltage and a small low current, thus the power supply device with high energy conversion efficiency can be used. Furthermore, because a current to be flowed is small and thin wiring can thereby be used, the two-dimensional surface-emitting laser array element 1000 including the elements and the power supply device can achieve compact size and lightweight.

As explained above, the two-dimensional surface-emitting laser array element 1000 can achieve high energy conversion efficiency and high integration with a simple structure.

In the two-dimensional surface-emitting laser array element 1000, the series-connected elements array 1001₁ to 1001ₙ are electrically connected in parallel to each other. Therefore, for example, even if one of the surface-emitting laser elements 100 forming the series-connected element array 1001₁ is degraded or damaged and the series-connected array element 1001₁ is thereby disconnected, the other series-connected array elements 1001₂ to 1001ₙ continue to operate. Moreover, effects of degradation of a surface-emitting laser element and heat generation due to the degradation stay within a range of the series-connected array element to which the degraded element belongs. As a result, a drastic degradation of optical power of the entire two-dimensional surface-emitting laser array element 1000 is prevented.

In the surface-emitting laser elements 100 forming the two-dimensional surface-emitting laser array element 1000, the upper DBR mirror 115 is formed with the dielectric material, and the current is injected from the p-side ring electrode 113 to the active layer 105 without passing through the upper DBR mirror. Consequently, as compared with the one in which the current is injected thereto through the upper DBR mirror formed from the p-type semiconductor as the conventional two-dimensional surface-emitting laser array element, the electrical resistance and the thermal resistance become small, and the power conversion efficiency of the surface-emitting laser elements 100 is high and satisfactory temperature characteristics are obtained.

Moreover, only a part of the upper DBR mirror 115 may be formed with a dielectric film and the other portions may be formed with a semiconductor film.

However, in the present invention, as the structure of the surface-emitting laser elements, it is not limited to the structure of the double-intracavity type. Thus, there may be used the surface-emitting laser elements constructed as the single-intracavity type in which the upper DBR mirror is formed with the semiconductor, the p-side ring electrode is formed on the upper side of the upper DBR mirror is adopted.

In the surface-emitting laser elements 100 that form the two-dimensional surface-emitting laser array element 1000, the n-type semiconductor layer is formed in the lower side of the active layer 105 and the p-type semiconductor layer is formed on the upper side thereof, however, the p-type semiconductor layer may be formed in the lower side thereof and the n-type semiconductor layer may be formed on the upper side thereof.

The two-dimensional surface-emitting laser array element 1000 is formed from the GaAs-based semiconductor material, however, the semiconductor material is not particularly limited thereto.

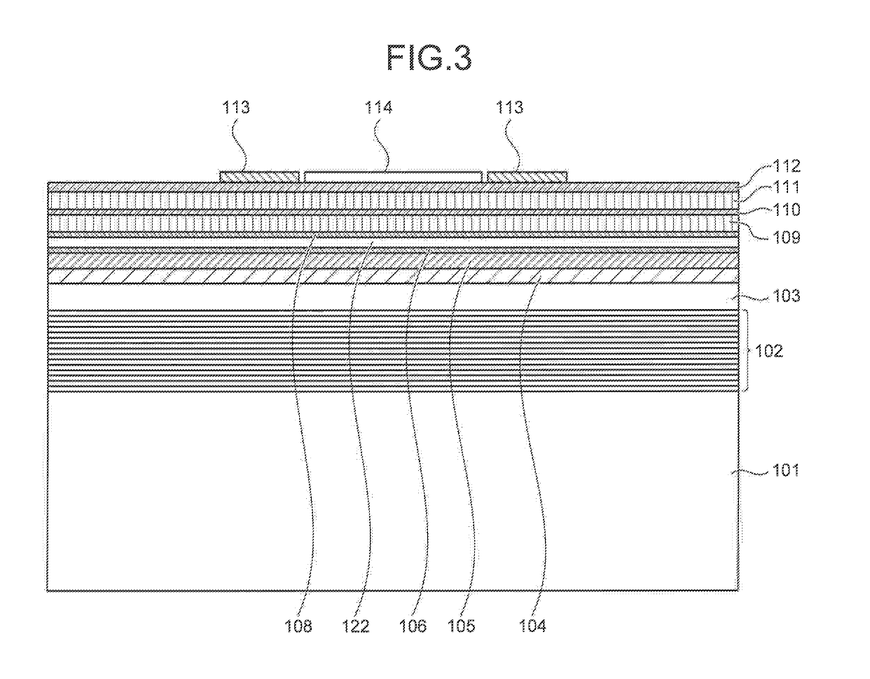

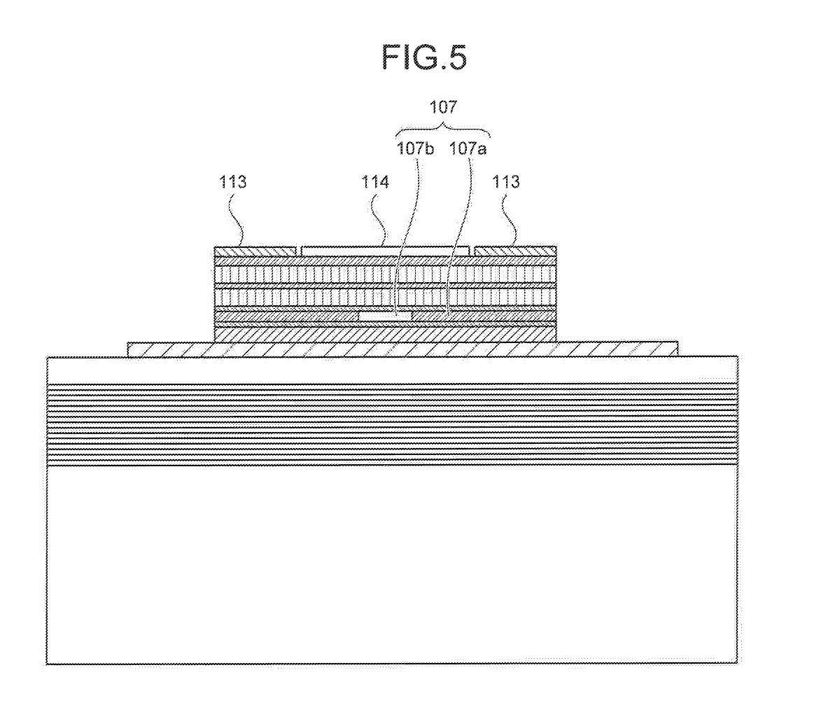

Next, a method for manufacturing the two-dimensional surface-emitting laser array element 1000 according to the first embodiment will be explained below. FIGS. 3 to 5 are explanatory diagrams for explaining one examples of the method for manufacturing the two-dimensional surface-emitting laser array element 1000 shown in FIGS. 1 and 2.

First, as shown in FIG. 3, the lower DBR mirror 102, the buffer layer 103, the n-type contact layer 104, the active layer 105, the lower gradient composition layer 106, an oxidized layer 122 made of AlAs, the upper gradient composition layer 108, the p-type spacer layer 109, the p⁺-type current path layer 110, the p-type spacer layer 111, and the p⁺-type contact layer 112 are sequentially laminated on the substrate 101 by using an epitaxial growth method. Then, the disk-shaped phase adjustment layer 114 made of SiNₓ is further formed on an area of the p⁺-type contact layer 112, on which the surface-emitting laser elements are to be formed, by using a CVD method. Each thickness of the layers is preferably adjusted so that the active layer 105 is positioned at nearly the anti-node portion of the standing wave of light and that the p⁺-type current path layer 110, the oxidized layer 122, and p⁺-type contact layer 112 are positioned at nearly the node of the standing wave of the light. Next, the p-side ring electrode 113 is formed on the p⁺-type contact layer 112 by using a lift-off method so that the phase adjustment layer 114 is disposed inside the opening 113a.

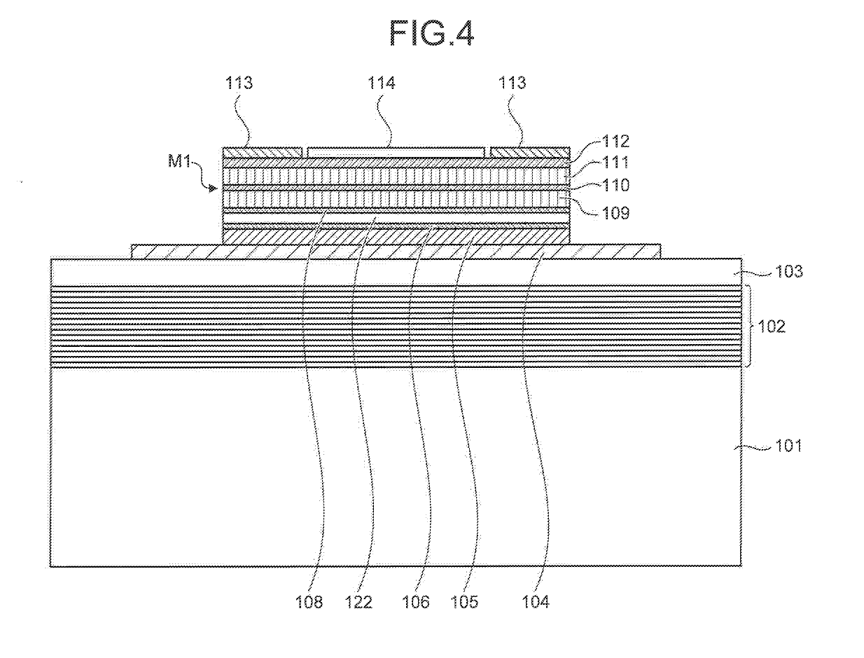

Next, by using the p-side ring electrode 113 as a metal mask, the semiconductor layer is etched to a depth as deep as the n-type contact layer 104 using acid etching solution or the like, to form the cylindrical mesa post M1. Then, another mask is further formed, and the n-type contact layer 104 is etched to a depth as deep as the buffer layer 103. As a result, a structure that the mesa post M1 shown in FIG. 4 is formed is obtained. It should be noted that because the p-side ring electrode 113 is used as a metal mask, the outer periphery of the p-side ring electrode 113 and the outer periphery of the mesa post M1 coincide with each other with high precision.

Then, a thermal process is performed in a water-vapor atmosphere, and the oxidized layer 122 is selectively oxidized from the outer peripheral side of the mesa post M1. At this time, a chemical reaction such as AlAs+H₂O→Al₂O₃+AsH₃ occurs in the oxidized layer 122, and AlAs becomes Al₂O₃ from the outer peripheral side of the oxidized layer 122, so that the current confinement portion 107a is formed. Because the chemical reaction progresses uniformly from the outer peripheral side of the oxidized layer 122, the current injection portion 107b made of AlAs is formed at the center thereof. Here, thermal processing time or the like is controlled so that the diameter of the current injection portion 107b is 6 μm to 7 μm. Because the current injection portion 107b is formed in this manner, the center of the mesa post M1, the center of the current injection portion 107b, and the center of the opening 113a of the p-side ring electrode 113 can be made coincide with each other with high precision.

Next, the semi-circular n-side electrode 116 is formed on the surface of the n-type contact layer 104 provided on the outer peripheral side of the mesa post M1. Then, after the passivation film 117 is formed over the entire surface thereof, openings are formed in the passivation film 117 on the n-side electrode 116 and the p-side ring electrode 113. The extraction electrode 118 is formed so as to connect the adjacent n-side electrode 116 and the p-side ring electrode 113 through the openings, and the common n-side electrode 1002 and the common p-side electrode 1003 are further formed.

Next, after the upper DBR mirror 115 is formed using the CVD method, the back side of the substrate 101 is polished, and the thickness of the substrate 101 is adjusted to, for example, 150 μm. Thereafter, the elements are separated from each other, and the two-dimensional surface-emitting laser array element 1000 shown in FIG. 1 is then completed.

In the two-dimensional surface-emitting laser array element 1000, when m is 50 and n is 10, the series-connected elements array 1001₁ to 1001₁₀, each in which 50 pieces of surface-emitting laser elements 100 are serially connected to each other, are connected in parallel to each other (hereinafter, “50×10 surface-emitting laser array elements”), and optical power with respect to drive current of the elements is calculated for simulation. FIG. 6 is a graph representing a relationship between the drive current and the optical power of 50×10 surface-emitting laser array elements. The drive voltage is set to 100 V at 100 mA. As shown in FIG. 6, an optical power of about 3.3 W when the drive current is 100 mA and an optical power of about 6.2 W when the drive current is 200 mA are obtained respectively.

### Second Embodiment

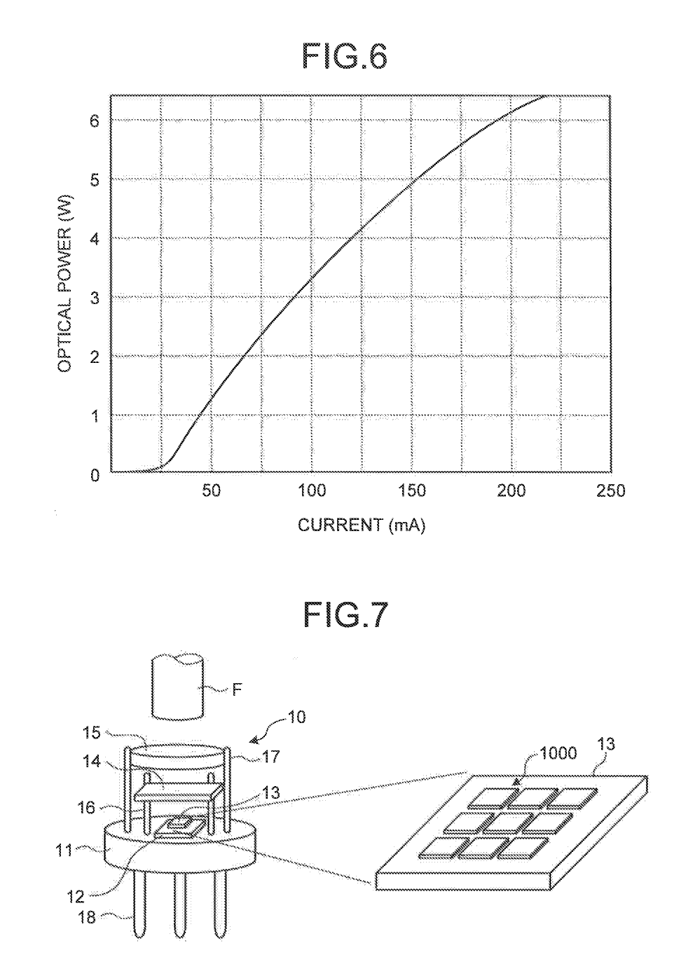

Next, a surface-emitting laser device according to a second embodiment of the present invention will be explained below. FIG. 7 is a schematic diagram illustrating a schematic structure of a surface-emitting laser device 10 according to the second embodiment and an enlarged part of the structure. As shown in FIG. 7, the surface-emitting laser device 10 includes a base 11; a heat sink 12 and a substrate 13 sequentially mounted on the base 11; nine two-dimensional surface-emitting laser array elements 1000 shown in FIG. 1 mounted on the substrate 13; a micro lens array 14 and a condenser lens 15 sequentially arranged above the two-dimensional surface-emitting laser array elements 1000; supports 16 and 17 which are disposed upright on the base 11 and support the micro lens array 14 and the condenser lens 15 respectively; and electrodes 18 arranged on the back side of the base 11. In addition, an optical fiber F is provided near the condenser lens 15.

The base 11, the heat sink 12, the substrate 13, and the supports 16 and 17 are made of a material such as metal or aluminum nitride. Moreover, the two-dimensional surface-emitting laser array elements 1000 are appropriately wired on the substrate 13 and are electrically connected to the electrodes 18. The surface of the micro lens array 14 is micro-processed so that collimating lenses are arranged in a two-dimensional array shape, similarly to the one disclosed in Nonpatent Document 1.In this way, the micro lens array 14 is structured so that each of the laser lights output from the surface-emitting laser elements 100 that form each of the two-dimensional surface-emitting laser array elements 1000 is changed to collimated lights. In addition, the condenser lens 15 is, for example, a spherical or aspherical convex lens and is structured so as to condense the laser lights as the collimated lights changed by the micro lens array 14.

The surface-emitting laser device 10 is structured so that the micro lens array 14 changes each of the laser lights output by the two-dimensional surface-emitting laser array elements 1000 to collimated lights and that the condenser lens 15 condenses the collimated lights and outputs the condensed lights. The output watt-class high-intensity laser lights are coupled to the optical fiber F, propagate along the optical fiber F to be carried to a desired location, and, thereafter, the laser lights are used for various purposes such as an pumping light for an optical amplifier, a laser light for laser processing, and a laser light for thermal process.

It should be noted that the number of two-dimensional surface-emitting laser array elements 1000 provided in the surface-emitting laser device 10 can be appropriately selected according to required intensity of the laser lights. Moreover, the condenser lens 15 is removed from the surface-emitting laser device 10, so that the collimated lights output from the micro lens array 14 may be used as they are for the various purposes.

The substrate 13 on which a plurality of two-dimensional surface-emitting laser array elements 1000 are formed can also be used as various types of light source without using the micro lens array 14, unlike the surface-emitting laser device 10.

In the light source, by equalizing the emission wavelengths of the surface-emitting laser elements forming each of the two-dimensional surface-emitting laser array elements 1000, the light source can be used as a light source with single wavelength, or by making different at least parts of the emission wavelengths of the surface-emitting laser elements, the light source can also be used as a multi-color light source. In this case, the emission wavelengths of the adjacent surface-emitting laser elements 100 are made different from each other, so that interference of the laser lights emitted from the adjacent surface-emitting laser elements can also be prevented.

### Industrial Applicability

As explained above, the two-dimensional surface-emitting laser array element according to the present invention is appropriate as a high-power light source.

### Reference Signs List

10 Surface-emitting laser device

11 Base

12 Heat sink

13 Substrate

14 Micro lens array

15 Condenser lens

16, 17 support

18 Electrode

100 Surface-emitting laser element

101 Substrate

102 Lower DBR mirror

103 Buffer layer

104 n-type contact layer

105 Active layer

106 Lower gradient composition layer

107 Current confinement layer

107a Current confinement portion

107b Current injection portion

108 Upper gradient composition layer

109, 111 p-type spacer layer

110 p⁺-type current path layer

112 p⁺-type contact layer

113 p-side ring electrode

113a Opening

114 Phase adjustment layer

115 Upper DBR mirror

116 n-side electrode

117 Passivation film

118 Extraction electrode

122 Oxidized layer

1000 Two-dimensional surface-emitting laser array element

1001₁ to 1001ₙ Series-connected elements array

1002 Common n-side electrode

1003 Common p-side electrode

F Optical fiber

M1 Mesa post

1.-10. (canceled)

11. A two-dimensional surface-emitting laser array element comprising:
a plurality of surface-emitting laser elements each of which includes
a substrate;
a lower multilayer film reflective mirror and an upper multilayer film reflective minor that are formed on the substrate and are formed from a periodic structure of a high-refractive index layer and a low-refractive index layer;
an active layer provided between the lower multilayer film reflective minor and the upper multilayer film reflective minor;
a lower contact layer positioned between the active layer and the lower multilayer film reflective mirror, and is extended to an outer peripheral side of the upper multilayer film reflective minor;
a lower electrode formed on a surface of a portion where the lower contact layer is extended; and
an upper electrode for injecting a current to the active layer, wherein
the surface-emitting laser elements are electrically connected in series to each other to form a plurality of series-connected element arrays, and the series-connected element arrays are electrically connected in parallel to each other.

12. A two-dimensional surface-emitting laser array element comprising:
a plurality of surface-emitting laser elements each of which includes
a substrate;
a lower multilayer film reflective mirror and an upper multilayer film reflective minor that are formed on the substrate and are formed from a periodic structure of a high-refractive index layer and a low-refractive index layer;
an active layer provided between the lower multilayer film reflective minor and the upper multilayer film reflective mirror;
a lower contact layer positioned between the active layer and the lower multilayer film reflective mirror, and is extended to an outer peripheral side of the upper multilayer film reflective mirror;
a lower electrode formed on a surface of a portion where the lower contact layer is extended;
an upper contact layer positioned between the active layer and the upper multilayer film reflective mirror; and
an upper electrode that is provided on the upper contact layer and injects a current to the active layer, wherein
the surface-emitting laser elements are electrically connected in series to each other to form a series-connected element array.

13. The two-dimensional surface-emitting laser array element according to claim 12, comprising the series-connected element array provided in plurality, wherein the series-connected element arrays are electrically connected in parallel to each other.

14. The two-dimensional surface-emitting laser array element according to claim 11, wherein at least part of the upper multilayer film reflective minor is formed from a dielectric material.

15. The two-dimensional surface-emitting laser array element according to claim 11, wherein the surface-emitting laser elements form a one-dimensionally arranged and serially connected element array.

16. The two-dimensional surface-emitting laser array element according to claim 11, wherein the upper electrode of the surface-emitting laser element and the lower electrode of the surface-emitting laser element adjacent thereto are connected to each other with an extraction electrode.

17. The two-dimensional surface-emitting laser array element according to claim 11, wherein in the series-connected element array provided in plurality, the surface-emitting laser elements forming the series-connected element arrays adjacent to each other are mutually displaced from each other in a longitudinal direction of the series-connected element array.

18. A surface-emitting laser device comprising:
a two-dimensional surface-emitting laser array element according to claim 11; and
a micro lens array that changes a laser light output from each of the surface-emitting laser elements forming the two-dimensional surface-emitting laser array element to a collimated light.

19. A light source formed from a two-dimensional surface-emitting laser array element according to claim 11, wherein emission wavelengths of the surface-emitting laser elements are equal to each other.

20. A light source formed from a two-dimensional surface-emitting laser array element according to claim 11, wherein at least part of emission wavelengths of the surface-emitting laser elements is different from emission wavelengths of the other surface-emitting laser elements.

21. The two-dimensional surface-emitting laser array element according to claim 12, wherein at least part of the upper multilayer film reflective minor is formed from a dielectric material.

22. The two-dimensional surface-emitting laser array element according to claim 12, wherein the surface-emitting laser elements form a one-dimensionally arranged and serially connected element array.

23. The two-dimensional surface-emitting laser array element according to claim 12, wherein the upper electrode of the surface-emitting laser element and the lower electrode of the surface-emitting laser element adjacent thereto are connected to each other with an extraction electrode.

24. The two-dimensional surface-emitting laser array element according to claim 12, wherein in the series-connected element array provided in plurality, the surface-emitting laser elements forming the series-connected element arrays adjacent to each other are mutually displaced from each other in a longitudinal direction of the series-connected element array.

25. A surface-emitting laser device comprising:
a two-dimensional surface-emitting laser array element according to claim 12; and
a micro lens array that changes a laser light output from each of the surface-emitting laser elements forming the two-dimensional surface-emitting laser array element to a collimated light.

26. A light source formed from a two-dimensional surface-emitting laser array element according to claim 12, wherein emission wavelengths of the surface-emitting laser elements are equal to each other.

27. A light source formed from a two-dimensional surface-emitting laser array element according to claim 12, wherein at least part of emission wavelengths of the surface-emitting laser elements is different from emission wavelengths of the other surface-emitting laser elements.
